(19) United States
(12) Patent Application Publication
(10) Pub. No.: US 2024/0053682 A1
(43) Pub. Date: Feb. 15, 2024

(54) DEVICE AND METHOD FOR EMBOSSING MICRO- AND/OR NANOSTRUCTURES

(71) Applicant: EV Group E. Thallner GmbH, St. Florian am Inn (AT)

(72) Inventors: Jonas Khan, Passau (DE); Walter Zorbach, Munzkirchen (AT)

(73) Assignee: EV Group E. Thallner GmbH, St. Florian am Inn (AT)

(21) Appl. No.: 17/766,549

(22) PCT Filed: Nov. 19, 2019
(86) PCT No.: PCT/EP2019/081853

§ 371 Date: Apr. 5, 2022

(51) Int. Cl. G03F 7/16; G03F 7/00

(52) U.S. Cl. CPC G03F 7/161; G03F 7/0002

(57) ABSTRACT

The present invention relates to a device for embossing structures into an embossing material, having a structure punch for embossing the structures into the embossing material. The structure punch can be kept under a constant local expansion during embossing and separation from the embossing material.

The invention relates to a device and a method for embossing micro- and/or nanostructures according to the subsidiary claims.

In prior art, micro- and/or nanostructures are manufactured either photolithographically and/or with the help of imprint lithography. Imprint lithography is understood as a method in which micro- and/or nanometer-sized structures are embossed into a material by a punch. The material involves an embossing material applied to a substrate. Such imprint methods have increasingly gained importance in recent years, since they can be implemented faster, more effectively and more inexpensively than many photolithographic methods. In addition, it has been shown that the resolution achievable by means of imprint lithographic methods is by no means inferior to the resolution that can be attained with the help of photolithography. In some cases, such as in the so-called “first print”, a better resolution can be achieved with imprint lithographically than with conventional lithography.

Most embodiments of known devices are built into so-called mask aligners (English: mask aligner) or conceived as a standalone system, but are unable to process substrates larger than 300 mm. Aligners are especially suitable for special imprint systems, since they have already found widespread use in the semiconductor industry for photolithography. This made it advisable for suppliers to offer expansions and attachments that built upon already known mask aligner technology or could expand it. The advantage to mask aligners is first and foremost that they in most cases already provide optical systems, in particular lamp housings, for the in particular full surface illumination of the substrates, and hence the embossed embossing materials.

In addition to modified or expanded mask aligners, there also exist separate imprint systems that are built on and for special embodiments. These systems are most often alignment systems, which can align a punch to the substrate with high precision. These systems further are capable of generating a vacuum, special dispensing systems, etc. Such imprint systems also are only rarely able to emboss an embossing material onto a substrate of more than 300 mm.

There exist imprint systems that enable the manufacture of structures for display devices, i.e., displays, in particular curved or flat screens.

There are five known techniques in imprint lithography:
Micro- and/or nanocontact printing (p/nCP)
Replica molding (REM)
Micro-transfer molding (μTM) or nanoimprint lithography (NIL)
Micro molding in capillaries (MIMIC)
Solvent-assisted micro molding

As known, imprint punches can be divided into two large families: use can be made of hard punches (made out of metal, ceramic materials or voluminous glass or plastic) or so-called soft punches (made out of polymers, silicones, etc.).

Elastomeric punches are manufactured as the negative of a master. The master punch is a hard punch made out of metal, glass, quartz glass, plastic, or ceramic, which is manufactured once in correspondingly complex processes. As many elastomeric punches as desired can then be manufactured from the master. The elastomeric punches allow a compliant, uniform contact over large surfaces. They are to be separated from their master punch, as well as from the embossing products. This stems from a low surface energy of an elastomeric punch, which is achieved through functionalization, in particular coating. The elastomeric punches are easier to separate from the substrate than hard punches.

The automated realization of soft lithographic processes requires that the elastomer punch be supported by a carrier. Glass carrier substrates of varying thickness are currently used. However, the use of thick glass substrates causes the elastomeric punch to lose its flexibility, at least in part. Therefore, the glass carriers are sufficiently thin carriers made out of glass that provide the necessary stability for the elastomeric punch on the one hand, while being flexible enough to achieve the necessary flexibility on the other.

Other embodiments of elastomeric punches are manufactured as layer systems out of elastomer or out of polymer: The carrier elastomer can be a substantial factor in determining the mechanical properties, such as stability, elasticity, evenness, and roughness. The structures of the punch are generated out of the punch material, in particular by way of impressions from the master.

In particular, a master can be manufactured in a step-and-repeat process (S & R process). This is advantageous above all when very large masters have to be manufactured. The master is here manufactured using an additional master-master. In technical parlance, however, the master from which the soft punches are molded is most often referred to as the sub-master, and the master for manufacturing the sub-master as the master. The definitions can thus vary. It is disclosed that an in particular large-surface master (or sub-master) used for molding soft punches can be manufactured in a repeated embossing process (step-and-repeat process), which is characterized in that embossing takes place at a first location, after which the master-master (or master) is moved and thereafter embossed at least one more time.

It is further conceivable to use a master in a step-and-repeat process to directly emboss the elastomeric punch. This is advantageous above all when the elastomeric punch is very large. The master is here moved to a first position, where it embosses the elastomeric punch, and then moves to a second position differing from the first position, and embosses again. This process can be continued as often as necessary to generate an elastomer punch of any size. In particular, the individually embossed locations of the elastomeric punch can be seamlessly embossed.

In general, the use of rigid carriers hampers the automatic separation of the punch and substrate after the embossing process, making process automation and the industrial applicability of imprint lithography difficult.

Another general problem associated with punches is that they most often only have a limited size. As a result, it is not easily possible to emboss large surfaces. Roller punches are one option for continuous embossing, but they will not be discussed any further here. Only a very few, and above all no fully developed, systems or methods exist in prior art for embossing micro- and/or nanometer-sized structures on large substrates.

Another problem lies in detaching the punch from the surfaces. Punch detachment must be precisely controlled, so that the embossed structure and the punch do not become damaged while demolding the punch.

Another problem, in particular associated with punches for large substrates, lies in the fact that the pathways for embossing or for separating the substrate from the punch require at least double the pathway of a characteristic length of the substrate. As a consequence, such devices require an extremely large amount of expensive cleanroom space. In other words, the problem with detaching the punch lies in the fact that the space required for separating the punch from the embossing surface scales with the length or diameter of the punch if the separation is based upon a linear lifting motion. In other words, this method involves peeling the flexible punch from the substrate with high shearing forces.

For a linear lifting motion, a separating mechanism of an imprint device thus requires an experimentally determinable pathway that can be established by the length of the punch, elasticity of the punch and adhesive properties, and must be traversed by a punch side to separate the punch from the substrate. Since the length of a tangent lever is variable, the length of the tensioned punch changes. A change in the length of the punch changes the material tension without any additional compensation, which also implies a change in the dimensional stability of the punch.

Alternative embodiments of separating mechanisms use pulleys to make separation more efficient. The direction of the punch is changed on a pulley, so that the space required by the device can be diminished by comparison to embodiments without pulleys. Given a change in direction of the punch, a change takes place in the force effects, and hence in the individual components of the stress tensor in the punch, meaning that the constant dimensional stability of the punch is not ensured.

A constant dimensional stability of the punch cannot be ensured neither for a separating mechanism with tangent lever nor for pulleys, even though a constant dimensional stability of a punch during the entire embossing process is a fundamentally important aspect of all embossing processes.

Prior art as relates to the micro- and/or nanostructuring of surfaces comprises above all photolithography and the varying embossing techniques. The embossing techniques use either hard or soft punches. Above all embossing lithography techniques have recently caught on. and are supplanting the classic photolithography techniques. Among the embossing lithography techniques, above all the use of so-called soft punches is growing in popularity. The reason lies in the ease of punch manufacture, efficient embossing processes, very good surface properties of the respective punch materials, low costs, reproducibility of the embossing product, and above all in the ability to elastically deform the punch during embossing and demolding. Soft lithography uses a punch made out of an elastomer with a micro- or nanostructured surface, so as to manufacture structures within a range of 10 nm to larger than 1,000 μm.

Aside from the advantages to imprint lithography with soft punches, there is the disadvantage of the same technology resulting from the elasticity of the punch, so that the dimensional stability of the punch is not always ensured. This leads to inaccuracies and distortions in the imaged, embossed structures in comparison to the structures of the punch to be embossed. This material-related disadvantage is likewise at least reduced with the present invention.

It has proven disadvantageous that the structure punch is exposed to varying stresses while embossing the structures and separating the structure punch from the embossing material, which causes the distances between the structures of the structure punch to vary, so that the dimensional stability of the generated structures in the embossing material is not optimal.

Therefore, the object of the invention is to indicate an improved device and an improved method for embossing structures, in particular micro- and/or nanostructures, which no longer have the disadvantages of prior art, and which can ensure in particular an automation and a quicker processing of the substrates with improved dimensionally stable embossing structures.

This object is achieved with the subject matter of the independent claims. Advantageous further developments of the invention are indicated in the subclaims. The framework of the invention also encompasses all combinations of at least two features indicated in the specification, the claims and/or the figures. The indicated value ranges are also to include values lying within the mentioned boundaries disclosed as limiting values and be claimable in any combination.

The invention provides a device for embossing structures in an embossing material, with a structure punch for embossing the structures in the embossing material, wherein the structure punch can be held under a constant local expansion during the embossing and the separation of the embossing material.

The invention further provides a method for embossing structures in an embossing material, wherein a structure punch embosses the structures into the embossing material, wherein the structure punch is held under a constant local expansion during the embossing and the separation of the embossing material.

In the sense of this invention, the feature “constant” means that the local expansion at each location of the structure punch is at least approximately the same. This is understood as meaning that the local expansion varies by at most 100 ppm relative to the average value.

Preferably provided is an embossing roller for pressing the structures of the structure punch into the embossing material, wherein the embossing roller has tappets for lifting the structure punch after embossing. This advantageously eliminates the need for an additional separating device.

Preferably further provided is a device, wherein, after embossing is complete, the embossing roller with the structure punch can be moved or is moved from an end position on a separating path back to a starting point for renewed embossing. As a result, the next embossing process can be advantageously started without interruption.

In particular, the invention relates to a device for embossing micro- and/or nanostructures with a structure punch, wherein the structure punch has improved handling properties, wherein the structure punch has an improved dimensional stability, wherein the device makes it possible to separate the structure punch from the substrate in a structurally space-saving manner, and wherein the dimensional stability of the structure punch is retained during the embossing process.

Another invention relates to another device according to the invention for embossing micro- and/or nanostructures, wherein the transfer of structures to the embossing material takes place only with the deformation of the structure punch, without any exposure to a rearward force by the fluid- or embossing roller, and wherein the dimensional stability of the structure punch is retained during the embossing process.

The invention further relates to methods for embossing micro- and/or nanostructures, wherein the embossing methods enable an improved imprint- and punch dimensional stability via the regulated separation of the substrate from the structure punch, with the material stress in the structure punch in particular being regulated during embossing and during separation. As a result, the local expansion of the structure punch remains constant, thereby improving the dimensional stability of the structure punch, in particular of the embossing structures.

The invention relates the force acting on the punch, in particular during the separation process, thereby reducing the load placed on the structure punch, the carrier, as well as the imprint. The limited load elevates embossing quality, and increases the service life of the structure punch.

The novel separation process performed according to the invention with the separating device requires less space than conventional separating methods. In particular the area of the overall system can be reduced as a result, which in turn lowers the costs in the cleanroom.

A first embodiment of the device according to the invention consists of a substrate mount, the structure punch to be molded, fastening elements for the structure punch, the embossing roller and the separating device, and the components listed further below.

The device further comprises the guides, measuring systems, and energy and media supply (CDA, vacuum, process gases, cooling water. etc.), and the positioning and moving devices (drives, brakes, fixations, clamps, in particular active, vibration-dampened frame, etc.), and the in particular central control and/or regulating unit designed as a computer and/or as an FPGA).

In addition, a substrate coated with the embossing material is essential for a method according to the invention.

At least two productive operating states can be allocated to a device for embossing: the embossing state and the separating state. In the embossing state, a structure punch is molded. In the separating state, the structure punch is separated from the molded substrate.

The device uses varying components in the embossing state and in the separating state: accordingly, it makes sense to allocate the device parameters. The features of the device are preferably listed in the sequence of components enumerated above, and with a description of the relationship between the components.

### Substrate Mount

The substrate mount can fix a substrate coated with embossing material. Various fixation mechanisms can be used for this purpose.

The fixations can be
Mechanical fixations, in particular clamps,
Vacuum fixations, in particular individually actuatable/regulated vacuum paths or interconnected vacuum paths,
Electrical fixations, in particular electrostatic fixations,
Electronically actuatable and/or regulated fixations,
Magnetic fixations,
Adhesive fixations, in particular so-called Gel-Pak fixations,
Fixations with adhesive, in particular actuatable surfaces and/or

The vacuum fixation is the preferred type of fixation. The vacuum fixation preferably consists of several vacuum paths, which exit on the surface of the sample holder. The vacuum paths can preferably be individually actuated and/or regulated. Several vacuum paths can preferably be specifically combined, grouped, into vacuum path segments, which can be individually actuated, and thus evacuated or flooded. However, each vacuum segment is independent of the other vacuum segments. This provides the option of building up individually actuatable vacuum segments. The vacuum segments preferably have an annular construction. As a result, a substrate can be specifically, radially symmetrically fixated and/or released from the sample holder, in particular from the inside out. This is advantageous for rotationally symmetrical substrates.

For substrates with other shapes, such as rectangular substrates or panels, it is advantageous to divide up the vacuum segments parallel to the sides of the substrate. It is especially advantageous that the design or switching process for the vacuum segments be congruent in shape to the shape of the respective substrate. This enables a flexible use of the sample holder for variable substrate shapes. In particular, the substrates can have non-planar surfaces or freeform surface to be embossed.

The substrates can have any shape desired, but are preferably circular. In particular, the diameter of the substrates is industrially standardized. For wafers, the industry-standard diameters are 1 inch, 2 inches, 3 inches. 4 inches, 5 inches, 6 inches, 8 inches, 12 inches and 18 inches. However, the embodiment according to the invention can basically handle any substrate, regardless of its diameter. Rectangular substrates are commonly referred to as panels.

### Structure Punch and Fastening for the Structure Punch

The structure punch preferably has the following characteristic properties: The punch side contains the structures to be molded as a negative image. While molding the structure punch, the elevations of the structure punch will give rise to the depressions in the embossing material. Accordingly, the topography of the punch side will contain a negative of the desired topography.

The rear side of the structure punch is the surface lying opposite the punch side. An embossing roller preferably rolls along the rear side of the structure punch.

At least two opposing ends of the structure punch are used to fasten the structure punch in the device. Fastening elements are preferably used to fasten the structure punch.

In an especially preferred embodiment, the fastening elements can be integrated into the structure punch in part materially, and in part functionally.

The structure punch is fastened in the device with the punch side facing in the direction of the substrate holder. It is assumed that a substrate coated with embossing material is fixated on the substrate holder.

The actual positioning task involves aligning the embossing side of the punch to the substrate coated with embossing material. This is achieved by positioning the fastening means of the structure punch relative to the substrate holder in the device. Since the embodiments of the devices differ from each other, the focus will here be preferably placed on the actual positioning, embossing, and separating task. The device parameters required for this purpose can simply be derived from the parameters for the configuration, design, and operation of the device.

The structure punch is aligned relative to the substrate or analogously to the substrate holder in a relative motion, and they are adjusted to each other.

Various parameter sets will be introduced as the text continues. Numerous parameter sets relate to the statistical features involving accuracy and precision.

Accuracy is understood as a systematic error. A systematic error is when the expected value for a parameter statistically determined from the sample quantity deviates from the true value of the population. The greater the accuracy, the smaller the deviation value, meaning the smaller the systematic error.

Precision is understood as the scattering of a measurement value around the expected value of the sample quantity. The greater the precision, the smaller the scattering.

Prior to embossing, the structure punch is preferably uniaxially evenly clamped above the surface of the embossing material by means of fastening elements. The structure punch is preferably set at an angle of less than 10 degrees, preferably of less than 6 degrees, especially preferably of less than 3 degrees, and optimally of less than 1 degree, and ideally parallel to the substrate.

The free distance between the structure punch and embossing material prior to embossing measures less than 1 mm, preferably less than 500 micrometers, especially preferably less than 50 micrometers. In especially preferred embodiments, the free distance between the structure punch and embossing material prior to embossing measures less than 10 mm, especially preferably less than 25 micrometers, very especially preferably less than 10 micrometers, and optimally less than 5 micrometers.

In a preferred embodiment, the structure punch can be reinforced, in other words supported, by a carrier. Thin, optically homogenous. mechanically isotropic materials can be used as the carrier, in particular films.

The following materials and/or combinations thereof and/or blends thereof can be used for the material of the carrier:
Glass (borosilicate, fluorinated, sapphire glass)
Polydimethylsiloxane (PDMS)
Perfluoropolyether (PFPE)
Polyhedral oligomeric silsesquioxane (POSS)
Polydimethylsiloxane (PDMS)
Tetraethyl orthosilicate (TEOS)
Poly(organo)siloxane (silicone)
Thermoplastics
Thermosetting plastics
Polymers
Elastomers
Polyimides (PI)
Polyethylene terephthalate (PET)
Polyamides and/or
Carbon.

All listed materials can also be used as fiber materials.

In preferred embodiments, in particular the carriers can be manufactured in shaping processes, in particular such as casting, injection molding, rolling, and blow molding.

The material for the structure punch [can] have at least one of the following materials or combinations thereof and/or blends thereof.
Polydimethylsiloxane (PDMS)
Perfluoropolyether (PFPE)
Polyhedral oligomeric silsesquioxane (POSS)
Polydimethylsiloxane (PDMS)
Tetraethyl orthosilicate (TEOS)
Poly(organo)siloxane (silicone)
Thermoplastics
Thermosetting plastics
Polymers
Elastomers.

In especially preferred embodiments of an in particular assembled structure punch, the carrier can achieve an advantageous functional integration through spatial shaping. The fastening elements can be manufactured at least in part with the carrier, in particular in a shaping process.

The thickness of the carrier is variable in this embodiment. The carrier has one part, a zone with a first, in particular homogeneous thickness in the area of the structure punch, wherein this part is molded, and another part, another zone with a second, variable thickness, which in particular can be designed as the fastening element.

In another embodiment, sensors, in particular force measuring sensors, or optical refraction-preferably double refraction-sensors, polarization sensors, can be arranged at the edge zone of the first, homogeneous thickness of the structure punch. The electrical contacts and/or optical couplers of the evaluation electronics are correspondingly integrated on the fastening element in the additional zone in the volume of the carrier.

In this advantageous embodiment, the expansion properties of all enumerated components (carriers, sensors, supply lines, structure punches, contacts) are synchronized.

### Embossing Roller

The embossing roller is preferably a cylindrical or barrel-shaped (rotationally ellipsoidal) body with a well-defined rotational axis and a shell surface. In other words, the embossing roller is a roller, an at least unilaterally driven roller guided, in particular mounted, at one end. Mounting the embossing roller makes it possible to rotate the embossing roller, and guiding the embossing roller allows a translational motion of the embossing roller along the guide.

In special embodiments, the embossing roller is a rotationally ellipsoidal roller, which can be used to emboss substrates that are not flat.

For embossing purposes, the shell surface of the embossing roller is brought into contact with the rear side of the structure punch, so as to mold the embossing side of the structure punch into the embossing material.

The surface quality of the shell surface is preferably manufactured at least in a polished, preferably lapped quality. Put another way, the embossing roller is preferably “smooth as glass”, regardless of the material used.

The embossing roller is mounted or guided at least at one end, so that it can carry out the motions necessary for embossing.

An embossing roller according to the invention has a shell surface diameter of greater than 10 mm, preferably of greater than 15 mm, especially preferably of greater than 30 mm, very especially preferably of greater than 70 mm, and optimally of greater than 120 mm. Smaller substrates or smaller structure punches are preferably embossed with embossing rollers with a smaller diameter than large-surface substrates and/or panels.

The embossing roller will execute the embossing process starting at a specific initial position, to which end the corresponding control loops, measuring systems and drives are switched and regulated. The embossing roller deflects the structure punch, so that the structure punch comes into contact with the embossing material. To this end, in particular a linear force of the embossing roller is exerted on the rear surface of the structure punch. The embossing roller preferably deflects the structure punch in such a way that the capillary forces of the embossing material are sufficient to pull in the structure punch.

The force ratio between the capillary force of the embossing material exerted on the structure punch, which is calculated as a linear force, and the force exerted by the embossing roller on the structure punch is 100:1, preferably 50:1, especially preferably 10:1. The force resulting from the capillary force and the linear force of the embossing roller (possibly also the gravitational force) performs the shaping work of the embossing material. In additional embodiments. the force ratio between the capillary force and the force exerted by the embossing roller on the structure punch measures 2:1, especially preferably 1:1, very especially preferably 1:5, and in another instance 1:10.

In another preferred embodiment, the embossing force is at least partially adjustable, especially preferably regulable, and in particular constant.

The embossing force can be regulated by controllably adjusting and readjusting the embossing roller in the normal direction of the embossing stamp rear surface. In so doing, an embossing force of between 0 N and 50,000 N, preferably 0 N and 10,000, especially preferably 0 N and 1,000 N, very especially preferably 0 N and 150 N, is applied as the linear force.

The embossing force can be influenced, in particular regulated, by means of a variably adjustable, in itself homogeneously distributed mass of the embossing roller. The mass of the embossing roller can be adjusted with more weight added inside of the embossing material, such as a liquid, metal balls, sand, etc. In addition, the embossing force can be influenced, in particular regulated. by adjusting the capillary force between the structure punch and embossing material. To this end, the viscosity parameter can be influenced by means of solvent content, and/or temperature and/or additives.

The viscosity of the embossing material lies between 0.01 cpoise and 10,000 cpoise, preferably between 1 cpoise and 500 cpoise, and especially preferably between 2 cpoise and 300 cpoise.

The temperature of the embossing material (preferably also the temperature of the substrate and the substrate holder) is between 0° and 300° C., preferably between 150 and 120° C., and especially preferably between room temperature (in particular 20° C.) and 75° C.

The temperature fluctuation of the embossing material during embossing is less than +/−5 K, preferably less than +/−3 K. especially preferably less than +/−1 K, very especially preferably less than +/−0.5 K, and optimally less than +/−0.1 K.

As additives, the embossing material can contain fluxes and/or radical catchers and/or radical reducers and/or oxygen inhibitors, in particular based upon modified acrylates.

In a first embodiment, the embossing roller is an at least unilaterally driven roller that is guided, in particular mounted, at both ends. In the preferably rigid roller, the outer shell surface is preferably designed with an elastic material. The elastic material of the embossing roller preferably increases the static or rolling friction to the structure punch. Furthermore, the surface of the embossing roller with the elastic material, in particular a crosslinked polymer structure, picks up the smallest particles lying on the rear side of the structure punch, in particular reversibly, and embeds them in such a way that the particles do not influence the result of the imprint.

In particular, the embossing roller can signal a necessary cleaning due to the embedded particles during the embossing process with a signal change (color, birefringence, electrical conductivity).

This publication draws no distinction between a structure punch without a carrier or a structure punch with a carrier, so that the enumerated properties and features can relate to embodiments with and without carriers.

The embossing roller is preferably mounted so as to be secured against tilting. In a first embodiment, the embossing roller is unilaterally mounted with at least two guiding elements spaced apart from each other, so that rolling friction constantly arises as bearing friction. The drive side is the side not mounted. In other words, the embossing roller is mounted on one side with two bearings, so that it can travel along the guiding path, and the other side of the embossing roller has an in particular detachable coupling for force or actuating path coupling.

In a second embodiment of the embossing roller, both ends of the embossing roller are mounted and driven in a synchronized manner. This minimizes the shearing forces along the embossing roller, in particular on the structure punch.

During the embossing process, the structure punch in the embossing material is molded onto the substrate surface. In particular, the embossing roller can roll along the length of the structure punch with a constant speed, or travel through a specific speed profile. In particular, the shaping work performed is kept constant. This can take place with a variation in the speed of the embossing roller and/or with a variation, preferably influenced in a regulated manner, of the embossing force or embossing pressure.

The embossing roller preferably executes a rolling motion on the rear side of the structure punch, and in so doing at least partially performs the shaping work of the embossing material.

In one embodiment of the device, the guide for the embossing roller is at least one straight guide, preferably at least one prismatic straight guide. The guiding line of the straight guide preferably deviates from the ideal by less than 500 micrometers, preferably less than 100 micrometers, especially preferably less than 10 micrometers, and very especially preferably less than 1 micrometer, relative to the overall length.

Another guide for the embossing roller clamps a theoretical plane. The clamped plane, the embossing plane, is preferably congruent with the substrate surface to be embossed. It is especially preferred that the embossing plane be a plane that is clamped parallel to the substrate surface, offset by the structure punch thickness.

In an especially preferred embodiment of the device, the guide for the embossing roller contains two straight guides, which can be adjusted relative to each other by +/−15 degrees, preferably by +/−10 degrees, and especially preferably by +/−5 degrees, so that the embossing plane can be adjusted and readjusted. The adjustment has adjusting means for positioning the straight guides parallel to each other. The parallelism is better than 1 degree, preferably better than 0.5 degrees, and especially preferably better than 0.1 degree.

In additional preferred embodiments of the device according to the invention, the guide for the embossing roller is designed as a trajectory of the substrate surface to be embossed, which in particular is not flat. The embodiment of the guide for the embossing roller thusly described makes it possible to guide the embossing roller largely parallel to the substrate, which leads to an in particular constant residual layer thickness of the embossing material. In order to allow a variety of uses for the device, it is provided that the guide for the embossing roller in particular be automatedly retrofittable in design. The guide for the embossing roller here molds the respective substrate shape viewed as ideal.

If the guide for the embossing roller is used for guiding the embossing roller during the embossing process, it serves as a control curve for embossing; in other words, the embossing roller has an embossing path.

The embossing path can consist of specific positions, which are defined as the starting position or as the ending position in the embossing process. In the method described later, embossing begins from the starting position, and embossing ends in an ending position.

At the end of the embossing process, the embossing roller can initially remain in a specific end position, or return to a defined starting position.

In another embodiment, the embossing roller is passively made to rotate during the embossing process, so that the frictional force between the embossing roller and structure punch is sufficient for the embossing roller to travel the characteristic length of the structure punch during the embossing process, in particular with a lower slippage, and preferably without slippage.

In another embodiment according to the invention, the embossing roller has at least two drives. The drives move the embossing rollers regulated independently of each other, preferably expediently synchronized to each other, in a translational and rotational motion.

As a consequence, an embossing process like raking can be implemented, or in particular a slippage correction is possible, so that the speed of the embossing roller, the resultant angular speed, as well as the feed speed can be tailored to each other and adjusted in a regulated drive structure.

Slippage correction is a measure of how an in particular elastic embossing roller deviates from the ideally calculated process parameters while pressing an elastic structure punch into an elastic embossing material. The deviations can be interpreted as slipping or sticking, i.e., faster or slower rotations than the ideal angular speed calculated for the feed speed. The extent of the correction provides information about the actual frictional state. The slippage is preferably kept to a minimum via regulated slippage correction.

### Separating Means and Separating Mechanisms

The structure punch is separated from the embossed embossing material after the embossing material has cured, or at least after initiating the curing of the embossing material. As the condition for successfully separating the structure punch from the embossing material, it can be formulated that the adhesion of the embossing material to the structure punch is slight, and the dimensional stability of the embossed embossing material (English: pattern fidelity) after separation is such that the embossing material deformation measures less than 5%, preferably less than 2%, especially preferably less than 1%, and ideally less than 0.01%.

During separation, the structure punch and the substrate are separated from each other in a relative motion. For a successful separation, it thus makes no difference whether the substrate or punch are lifted off each other. The motion of the structure punch is expedient at this juncture.

As an in particular spatial guide, the separating means can contain a so-called separating path for the embossing roller.

The embossing roller can travel along the separating path starting at the defined end position after an embossing process. In other words, the separating path is a control curve, a spatial path. The separating path guides the embossing roller away from at least the substrate, preferably from the structure punch, so that the embossing roller is lifted from the substrate, and returns to a defined initial position essentially parallel to the embossing path.

The embossing roller has correspondingly designed tappets, which pick up the fastening elements of the structure punch and entrain them on the separating path. As a consequence, the structure punch is entrained and detached from the embossing material.

In other words, the structure punch is entrained in particular from the horizontal position by the tappet, in particular within the smallest space, preferably moved together with the embossing roller, so as to achieve a separation at a large separation angle. The material stress in the structure punch is held constant in the process.

The separation angle measures more than 0 degrees, preferably more than 30 degrees, especially preferably more than 90 degrees, very especially preferably more than 120 degrees, and optimally more than 160 degrees.

The tappet can establish a positive connection between the fastening elements of the structure punch and the embossing roller. The following basic structural ideas can be used as different embodiments of the tappet, either unmixed (both ends identically designed) or mixed, so that the tappets differ at the ends of the embossing roller:
Ball on plane pairing,
Ball on several planes (such as V-groove) pairing,
Cone in conical bore pairing,
Cylinder-U-groove pairing,
Cylinder-V-groove pairing, or also designed as a keyway,
Cylinder in cylinder pairing,
Prismatic element on plane,
Prismatic element in prismatic element,
Magnet with counter-piece, also designed as a switchable electromagnet,
Bayonet fastener,
Control curve and cylinder (self-locking control curve, spiral), and/or
Detachable snap lock.

The tappet can establish a nonpositive connection to the embossing roller through friction.

The tappet can establish an electromagnetic and/or permanent magnetic and/or electrostatic and/or vacuum connection to the embossing roller. No materially solid contact preferably takes place between the embossing roller and tappet. In other words, the tappet and embossing roller can be coupled via a fluid flow or (electro)magnetic or electrostatic coupling, and moved with correspondingly performed work.

A controlled detachment is achieved by optimizing the following parameters:
Height of the separating path relative to the embossing path,
Regulated tensile force of the embossing roller on the separating path, exerted on the fastening elements and structure punch,
Length of the separating path,
Trajectory (control curve of the motion) of the structure punch on the separating path,
Electrostatic tension for repelling the structure punch from the cured embossing material,
Selecting/influencing surface properties, in particular reducing the surface energy with corresponding coatings, and/or
Regulating the detachment temperature and/or thermally supporting the separating process, in particular with a targeted change in structural geometry utilizing the differences in thermal expansions of the substrate, the embossing material and the structure punch, knowing the thermomechanical time constants for the individual components. The thermomechanical gradients are used to design the separating process more quickly and effectively.

Let the following separating process be mentioned as an example: Rapidly warming the substrate and embossing substrate allows the substrate and embossing material to expand. The nonwarmed structure punch can be separated from the embossing material with less force expended than in an isothermal state.

After the structure punch has been successfully separated from the substrate, in particular a return mechanism takes the structure punch back into the embossing position, and fastens it accordingly.

Alternatively, the embossing roller guides the structure punch into the embossing position and travels into the initial position, without further influencing the structure punch.

### Method 1

A first method according to the invention for molding the structure punch in the embossing material on the substrate provides the following procedural steps.

Coating the substrate with the embossing material, as well as transporting and fastening the substrate to the substrate holder, fastening the structure punch in the device, etc., are understood as preparatory procedural steps, and not described in detail.

In a first procedural step, the embossing roller travels over the substrate wetted with the embossing material, and establishes the material contact between the structure punch and embossing material.

In a second procedural step, the embossing roller traverses the characteristic length of the structure punch, and molds in particular the entire surface of the structure punch in the embossing material. In other words, the embossing roller travels along the embossing path.

In a third procedural step, the embossing material is crosslinked. The embossing material can be cured over the entire surface. Alternatively, a following energy source can successively initiate the curing process.

In a fourth procedural step, the embossing roller reaches a specific end position of the structure punch.

In a fifth procedural step, the embossing roller is coupled to the structure punch with the tappet.

In a sixth procedural step, the embossing roller with the structure punch coupled thereto travels along the separating path, causing the structure punch to be separated out of the in particular cured embossing material.

In a seventh procedural step, the structure punch is completely separated from the embossing material. The embossed substrate is thereafter unloaded.

In an eighth procedural step, the structure punch and embossing roller are brought into the respective starting position. In a preferred embodiment, the embossing roller travels back down the separating path in the opposite direction, places the structure punch into the embossing position, detaches the tappet or several tappets, and returns to a starting position.

In another embodiment, the tappet is detached, a mechanism brings the structure punch into the embossing position, and the embossing roller travels back into the starting position on a defined additional path.

### Additional Devices According to the Invention (Deflected Structure Punch)

A second embodiment of the device according to the invention is a further development of the first embodiment of the device according to the invention, with a prestressing device for a regulated, constant expansion of the structure punch. The structure punch preferably has one carrier.

In particular, the structure punch is clamped with a regulated prestress, in particular with a controlled, in particular regulated, constant expansion. The constant expansion of the structure punch is maintained while manufacturing the structure punch and using the structure punch for molding the embossing material.

If the constant expansion cannot be maintained, a deviation from the constant expansion is kept from the constant expansion by less than 120 micrometers per 200 mm reference length (yields 100 ppm) of the expansion value, preferably less than 1 micrometer per 200 mm reference length (yields 5 ppm), especially preferably less than 500 nanometers per 300 mm reference length (yields 1.6 ppm), and very especially preferably less than 50 nanometers per 300 mm reference length (yields 16 ppb) [from the constant expansion].

This makes it possible to maintain an improved dimensional stability for the embossing structures. In particular, this allows the local dimensional stability of the embossing structures to be maintained by the constant local expansion of the structure punch. In other words, the goal is to minimize the change in expansion while embossing or while separating the structure punch, which leads to an improved dimensional stability.

For the present invention and the basic idea according to the invention, the constant local expansion is understood as a one-to-one effect of an in particular regulated prestress of the device that prestresses the structure punch.

In particular given structure punches made out of polymers or elastomers, the constant local expansion can be achieved with a regulated prestress, so that the relaxation of the material of the structure punch is considered, and the dimensional stability of the structure punch is improved and increased.

In a longitudinal section along the embossing punch, fastening points together with the variable embossing point form a right triangle, in particular with a hypotenuse having a constant length. The prescribed geometric condition stipulates an elliptical path for the constant expansion of the structure punch.

The error between the elliptical orbit traversed by the structure punch with the embossing roller and a plane for embossing is less than 5%, preferably less than 3%, and especially preferably less than 1%. This is achieved with the interpretation of geometric conditions, in particular with the distance of fastening points as 1.5 times the embossing length, preferably 2 times the embossing length, and especially preferably 4 times the embossing length.

In order to avoid the error of the elliptical orbit, it is advantageous according to the invention that a correspondingly nestling elliptical substrate be used.

In particular, so-called virtual reality glasses, curved displays such as televisions or computer screens can arise as possible applications. It is likewise possible to use the technology according to the invention for interactive vehicle windows, in particular a display (in particular curved shape) integrated into the windshield or interactive side windows for rail vehicles or buses (in particular flat shape).

The embossing roller prestresses the structure punch between the fastening elements, in particular in a regulated manner. The structure punch nestles itself against the embossing roller (during the embossing process) at a contact angle of less than 181 degrees, preferably less than 120 degrees, especially preferably less than 90 degrees, very especially preferably less than 45 degrees, and optimally less than 30 degrees.

In additional preferred embodiments, the contact angle between the structure punch and embossing roller is less than 5 degrees, preferably less than 3 degrees, and especially preferably less than 1 degree.

Large contact angles are achieved during the controlled separation of the structure punch with the help of the embossing roller. The aforementioned small contact angles measuring in particular below 30 degrees are preferred while embossing. The structure punch is preferably clamped in uniaxially.

In another preferred embodiment of the device, the prestress of the structure punch is adjusted with a control loop and actuators, in particular linear actuators on the structure punch, and the local expansion of the structure punch is held constant. The distance between the fastening points is here regulated in such a way that the elliptical orbit of the prestressed structure punch is variable, and in any position of the embossing roller always describes a tangential point of the embossing plane. The constant expansion of the structure punch is here maintained. This makes it possible to emboss planes or so-called freeform surfaces.

This is achieved by a structural convergence of the respective ellipsoid and plane via elastic and/or guided elements in a control chain or in a control loop. In an especially preferred embodiment, the flat shape of the structure punch to be molded on the embossing material is adjusted via the regulated expansion and specific change in length of the two legs of the theoretical right embossing triangle.

The free distance between the structure punch and embossing material (before embossing) measures less than 5 mm, preferably less than 1,000 micrometers, especially preferably less than 500 micrometers, and very especially preferably less than 100 micrometers prior to embossing.

In other especially preferred embodiments, the free distance between the structure punch and embossing material is further reduced to less than 50 micrometers, preferably less than 20 micrometers, especially preferably less than 10 micrometers, and very especially preferably less than 5 micrometers.

The free distance relates to a minimum between the structure punch and embossing material, so that consideration is likewise given in particular to the deflection and/or free suspension of the structure punch and/or the effect of electrostatic attraction, and effects of transient device oscillations.

A relative feed motion of the structure punch to the embossing material and to the substrate establishes the contact between the embossing material and structure punch.

The embossing material is cured simultaneously, preferably zone by zone, especially preferably linearly, very especially preferably with a slit projection of the curing beam. A slit projection can be construed as a slit lamp or an oscillating laser beam. The oscillation speed is here at least 100 times, preferably at least 1,000 times, especially preferably 10,000 times, higher than the speed of the embossing roller. so that the curing beam acts flatly and does not cure any lines separated from each other.

In another embodiment of the device, the embossing material is cured zone by zone in regulated intervals. The duration of the intervals in which the curing beam is and is not applied is determined in an iterative process, considering the minimization of the thermal load on the embossing material and structure punch. This regulation is known to the expert as pulse width modulation. However, other known regulating methods can be used.

In an especially preferred embodiment of the device according to the invention, at least the embossing roller and the curing source are functionally integrated into one unit. This yields an embossing roller unit.

The embossing roller unit can contain at least one embossing roller, an in particular identically designed support roller, and a radiation source with projection device.

In this preferred embodiment of the embossing roller, it is configured as a double, spaced apart roller pair with the curing device in between. The first roller traveling in the embossing direction is regarded as the embossing roller, the in particular continuously operating curing device crosslinks the embossing material, and the subsequent embossing roller as the support roller enables a controlled separation of the substrate punch from the cured embossing material.

In another embodiment, the embossing roller unit can have at least one embossing roller and a support roller. The support roller can integrate a radiation source, in particular a heat source. In other words, the one roller of the embossing roller unit is used as the embossing roller, while the other roller as the heated roller is used as a thermal curing device, and integrated into the embossing roller unit as a curing device. Another embodiment can have a radiation source for the crosslinking radiation, in particular a UV light source. The support roller is here transparent in design for the crosslinking radiation.

In an especially advantageous embodiment, the support roller and embossing roller in the embossing roller unit can change the distance between each other, in particular in a regulated manner, so as to adjust the stress of the structure punch. If the rollers are close together, the structure punch is less prestressed than when the rollers are kept at a maximum distance from each other. In particular, pantographs provided on both sides and prestressed with little play, especially preferably without play, can be used as the adjusting mechanisms. However, use can be made of any adjusting devices with a self-retaining capability and without play.

Strain sensors, in particular strain gauges, can be integrated into and/or onto the structure punch to regulate the prestress of the structure punch. In other embodiments of the structure punch, the strain gauges are fastened to the structure punch. Furthermore, load cells for the clamping force of the structure punch can be reconciled with the actual value in particular for several strain gauges. The measured stress of the structure punch can be regarded as the control variable. The positions of the rollers relative to each other adjusted individually or in combination and/or the position of the embossing roller unit and/or the position or clamping force of the holding device of the structure punch can be used for the controlled variables correlating thereto.

The time constant for regulation is preferably 1/10, especially preferably 1/100, and especially preferably 1/1,000 of the time constant for the fastest motion of the device. The regulating speed (speed of the actuators) is as fast as the fastest motion of the device.

In particular, the regulators are designed as computer programs and routines. While the regulators are especially advantageously designed for accuracy (accuracy of prestressing, positioning, dimensional stability) and speed, an overshoot, a surpassing of the control variable that deviates from the desired value, is not preferred. The control parameters derived from the difference of the desired value for the stress of the structure punch and from the actual value are designed in such a way as to preclude an “escalation”, an in particular harmonic oscillation, at any time during the embossing process and the separation process.

The mechanical stress on the structure punch lies between 0.001 MPa, and the respective yield strength of the structure punch (and/or of the carrier) preferably lies between 1 MPa and 2 MPa. If the yield strength of the structure punch is smaller than the yield strength of the carrier, the enumerated parameters for the structure punch apply. The mechanical stress parameters for the material with a lower yield strength generally apply. This makes it possible to prevent excessive stress from being placed on the structure punch.

The mechanical stress of the structure punch is especially preferably regulated. The mechanical stress of the structure punch can deviate by the least possible amount over time while embossing or while separating two substrates embossed one after the other. In other words, it is possible according to the invention for the prestress of the structure punch to change, and a regulated variable prestress to be used. The minimum for the deviation in prestress then relates to the repeatability of the identical procedural steps. An embossed substrate can thus be mechanically stressed with the mechanical stress of another embossed substrate with the lowest possible repetition error.

The same holds true for the mechanical stress held as constant as possible while separating the embossed substrate from the structure punch.

The error for mechanical stress is less than 10%, preferably less than 5%, and especially preferably less than 2%, relative to the desired value, in particular the desired value of the respective procedural step.

The error for expansion (and tied thereto dimensional stability) of the structure punch is less than 100 ppm, preferably less than 10 ppm, especially preferably less than 100 ppb, very especially preferably less than 10 ppb, and optimally less than 5 ppb relative to the ideal situation for dimensional stability.

Embossing with the device according to the invention with the embossing roller unit, wherein the prestress of the structure punch is controllably adjusted for a constant local expansion of the structure punch, is regarded as an independent method according to the invention.

### Additional Devices According to the Invention

(Semi-Elastic Structure Punch without Embossing Roller)

A third, especially preferred embodiment of the device has: at least one substrate mount, one structure punch to be molded, fastening elements for the structure punch, and a prestressing device. A substrate coated with embossing material is necessary for the method according to the invention. The properties of the described structure punch can be correspondingly carried over to the structure punch with embossing roller.

The structure punch consists of at least two areas, which allow a functional division of the structure punch:

There is a molding area, preferably symmetrically arranged over about half the characteristic length of the structure punch, and a holding area, preferably formed at least at two ends of the structure punch.

The molding area of the structure punch is preferably shaped congruently to the substrate. The holding area of the structure punch envelops the molding area on at least two sides.

On the punch side, the molding area has the structured surface of the structure punch to be molded. The molding area can have alignment marks, version numbers, control characters for the positioning device (aligner) and/or an illuminating device as a binary code or as a QR code, wherein the control characters or the alignment marks need not be imaged in the embossing material. In other embodiments of the structure punch, the alignment marks, version numbers. control characters for the positioning device (aligner) and/or the illuminating device can be secured to the side lying opposite the punch side, in particular in an unchangeable manner.

The molding area is preferably at least optically homogeneous and nonporous and free of outside shadows, and mechanically isotropic in design. If the structure punch has a carrier, the properties of the structure punch likewise relate to the carrier. The carrier preferably has a homogeneous thickness.

In another embodiment of the structure punch, the molding area is configured in such a way that specifically structuring the carrier or the structure punch in addition to the structures of the structure punch to be molded helps to minimize and/or homogenize a residual layer thickness of the embossed structures on the substrate. Preferably generated is a variation for the residual layer thickness of under 50 nanometers, especially preferably of under 10 nanometers, and very especially preferably of under 1 nanometer.

In other words, the structure-dependent residual layer thickness of the embossed structures can be adjusted.

In applications with removal processes after embossing, a minimized residual layer thickness is generally preferred.

A defined, adjustable, dimensionally stable residual layer thickness is preferred for optical applications, in particular diffractive optics, and waveguides (English: diffractive optical elements, DOE).

As can easily been seen, a residual layer thickness can turn out to be larger in absolute terms given structure sizes on a millimeter scale than given structure sizes on a nanometer scale.

In preferred embodiments of the structure punch, the boundary between the holding area and the molding area does not take the form of a defined line, but must rather be understood as an area with intermeshing functions.

The primary task of the holding area is to mount the structure punch in the device. The holding area can have the same material properties as the molding area, but deviate from the latter in terms of shape and/or thickness and/or additional functions and/or stiffnesses and/or information content.

In a first embodiment, the holding area is the material continuation of the molding area, with at least nearly the same thickness and stiffness.

In a second embodiment, the holding area is a material continuation of the molding area, with an altered thickness of the molding area and correspondingly modified stiffness. In particular, this embodiment is symmetrically half wedge- or wedge-shaped in design, so that the structure punch can be prestressed to an adjustable material stress, if possible free of notch stress.

In a third embodiment, the holding area is a material continuation of the molding area with formed solid hinges.

A fourth embodiment of the holding area can yield a combination of the second and third embodiments of the holding area: The holding area has solid hinges and wedge-shaped elements for fastening the structure punch in the device.

A fifth embodiment of the holding area has an unsymmetrically wedge-shaped cross section. The holding area has at least two flat deposit surfaces on the embossing side. The in particular flat deposit surfaces are offset relative to the molding surface of the structure punch. so that the molding area of the structure punch, when freely mounted and facing in a gravitational direction, does not come into contact with a support surface on which the deposit surface rests. In other words, the structure punch rests at the edge on a deposit surface, and the embossing side does not come into contact with the deposit surface, and is further held with the inherent rigidity.

In particular, the stiffness of the holding area and the embossing area is such that the structure punch lying freely on a support surface, preferably on both support surfaces lying at both ends of the punch, does not contact the support surface, despite sagging like a stiff plate with the molding area.

The deposit surfaces provide the ability to easily store the structure punch outside of the device without contamination. Another advantage to the embodiment is that a prescribed direction of the structure punch stipulates the assembly direction of the structure punch in the device. Additional asymmetries of the structure punch can be used to ensure a one-to-one location and position of the structure punch in the device. These measures implement the lock-and-key principle.

A combination of the fifth embodiment and the second and/or third embodiment is regarded as especially advantageous.

In particular, the structure punch is fastened in the device with positive fastening elements. In addition to a fastening function, the fastening elements as well as the structure punch are further functionalized correspondingly to each other. In particular, precisely one correct installation position of the structure punch is achieved by using the lock-and-key principle, in particular with asymmetrically placed molding elements or an asymmetrical formation of the structure punch.

In particular, the design of a structure punch according to the invention is the result of simulation and numeric approximation (finite element method, FEM), wherein parameters of a simulated embossing process for optimizing residual layer thicknesses of the embossing material influence the dimensional stability and service life of the structure punch. If the structure punch thickness is inhomogeneous in design, the stiffness, and the optical path length of crosslinking, curing radiation or heat transfer is best configured according to the numeric optimization. In this way, complex, flexible hinges for the structure punch can produce both a uniform. constant prestress for the structure punch and nearly distortion-free embossing structures.

As a consequence, in particular semi-elastic structure punches can be developed, simulated and manufactured, wherein the material expansion of the structure punch can preferably be held constant, and wherein with a correspondingly adjusted material thickness and/or material stiffness of the structure punch, the molding area of the structure punch retains a greater flatness and/or a greater dimensional stability during embossing than the holding area. In particular solid hinges made out of the punch material/carrier material of the structure punch enable a deformation of the structure punch for embossing through exposure to a force exerted by the structure punch. In particular, the structure punch can assume two shapes from an acting force or without an acting force, which have the effect of a resting state of the structure punch or a prestressed, stable position of the structure punch for embossing.

The structure punch is preferably configured in such a way that the neutral fibers of the structure punch remain permanently on the embossing surface. According to the invention, it is conceivable that the molding surface be exposed to a constant tensile stress, which does not change during the embossing process (beginning with the manufacture of the structure of the structure punch). For this purpose, the device can be correspondingly regulable in design.

As a result, the embossing structures of the structure punch are manufactured free of mechanical stresses, so that the separating force is the largest variable force. The separating force has an approximately normal effect on the embossing structures, thereby yielding an improved dimensional stability of the embossing structures and the structure punch.

A device according to the invention receives the structure punch in a punch holder with translational and rotational degrees of freedom and positioning systems. The structure punch and the substrate coated with embossing material are brought closer together to each other. Embossing is performed by bending the structure punch via the feed motions of the positioning systems. The structure punch is separated after the embossing material has cured in a reversal of the embossing motion.

In other words, the moldability of the structure punch can result from the bending motion, wherein no external force preferably acts on the rear side of the punch surface other than gravitational force. In particular the molding surface will here reversibly deform less than 20% of the critical structure dimension, preferably less than 5% of the critical structure dimension, especially preferably less than 1%, and very especially preferably less than 0.1% of the critical structure dimension, while the holding area performs a macroscopic motion for embossing purposes. As a consequence, a bending motion of the structure punch is used for embossing. The shaping work of embossing consists of the embossing force and path covered. The effect of capillary forces as well as the resultant bending motion of the structure punch will perform the shaping work.

As a consequence, the device does not require a separating device or an embossing roller.

Additional advantages, features and details of the invention may be gleaned from the following description of preferred exemplary embodiments. as well as based on the drawings. The latter show:

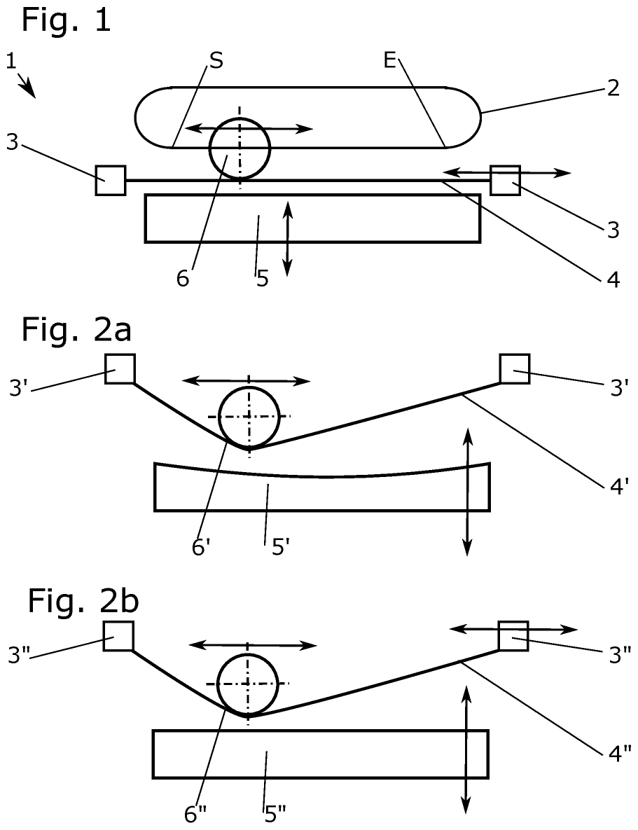

FIG. 1 Schematic structural sketch of a first embodiment according to the invention of a device according to the invention

FIG. 2a Schematic structural sketch of a second device according to the invention in a first embodiment

FIG. 2b Schematic structural sketch of a second device according to the invention in a second embodiment

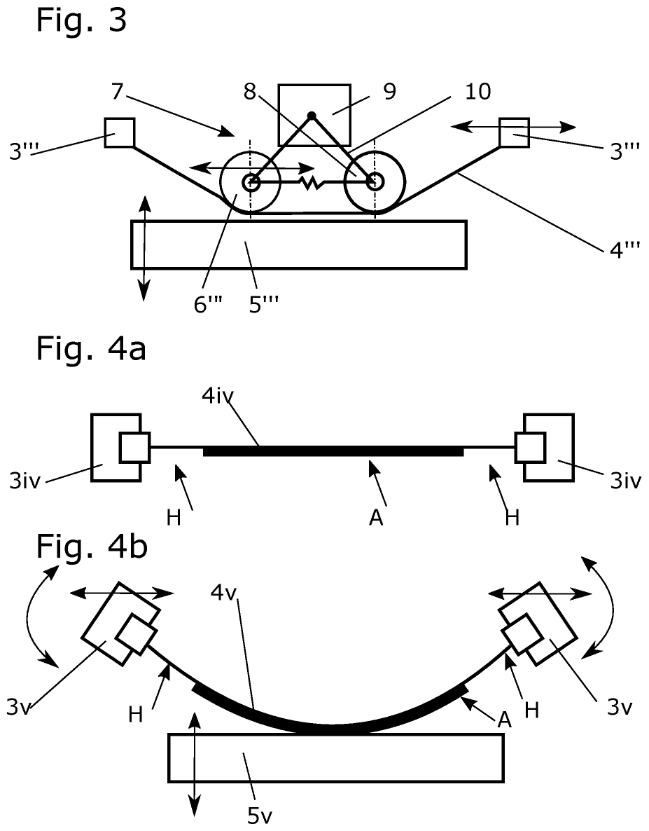

FIG. 3 Schematic structural sketch of another device according to the invention

FIG. 4a Schematic structural sketch of a structure punch

FIG. 4b Schematic structural sketch of the application of the structure punch on FIG. 4a in a device according to the invention

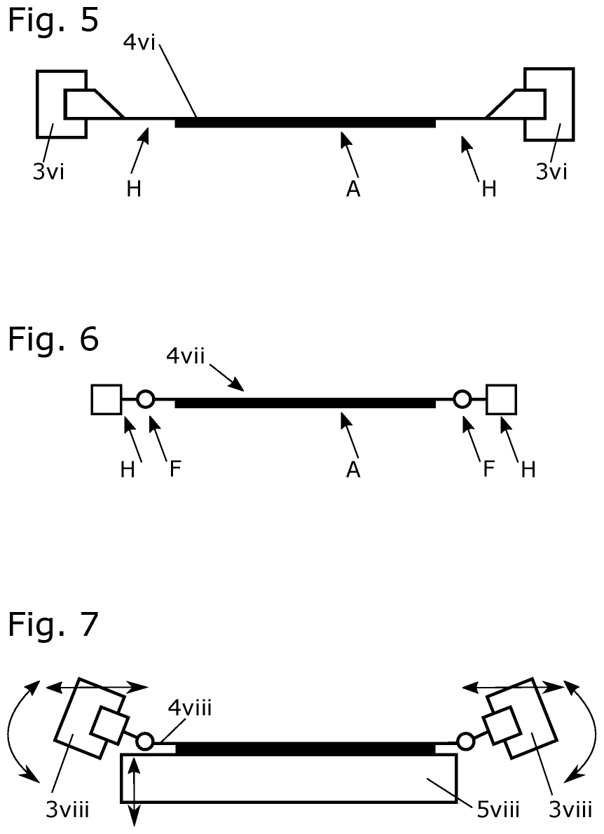

FIG. 5 Schematic structural sketch of the application of the structure punch on FIG. 4b in a device according to the invention

FIG. 6 Schematic structural sketch of a third embodiment of a structure punch

FIG. 7 Schematic structural sketch of the application of the structure punch on FIG. 6 in another device according to the invention

On the figures, the same components or components with the same function are labeled with the same reference number.

FIG. 1 shows a schematic structural sketch of a first embodiment according to the invention of an embossing device 1 according to the invention. A structure punch 4 is held under a constant expansion by means of fastening elements 3. The constant, in particular adjustable expansion of the structure punch is denoted by the arrow of a fastening element 3. The device 1 uses an in particular regulated mechanical force for this purpose, which as a mechanical stress in the structure punch 4 enables a constant local expansion.

An undepicted substrate coated with embossing material is fastened to a substrate holder 5, and the structure punch 4—after bringing the structure punch 4 into contact with the embossing material—is molded in the embossing material. To ensure a sufficient formability, an embossing roller 6 presses the structure punch 4 into the embossing material.

The separating device 2, here depicted as a path, is used for separating the structure punch 4 from the substrate.

The separating device 2 is structurally and materially connected with the embossing path between a starting position S and an ending position E. If the embossing roller 6 is on the segment between S and E, the structure punch 4 is molded, and embossing takes place. If the embossing roller 6 is located between E and S outside of the embossing path on the separating path, undepicted tappets correspondingly pick up the structure punch 4, so that the structure punch 4 can be separated from the substrate.

In particular to support the separating process, the substrate holder 5 can likewise be moved. The optional relative motion is denoted by the arrow.

FIG. 2a shows a schematic structural sketch of a second device according to the invention in a first embodiment. A structure punch 4′ is preferably fixedly fastened in the undepicted embossing device by means of fastening elements 3′. An embossing roller 6′ prestresses the structure punch 4′ under a constant expansion, so that the structure punch 4′ can emboss the undepicted substrate coated with embossing material. The substrate is fastened to a substrate holder 5′. The substrate holder 5′ can be delivered, in particular delivered in a regulated manner. This can be used to adjust the embossing force as well as to adjust the normal force while separating the structure punch 4′ from the substrate. In other embodiments, the substrate holder 5′ cannot be delivered, so that the additional feed motions are performed by the structure punch, fastening elements, etc.

In particular, the depicted embodiment is suitable for embossing curved, in particular elliptical substrate surfaces. This is symbolically depicted with the curvature of the substrate holder 5′.

FIG. 2b shows a schematic structural sketch of the second device according to the invention in a second embodiment. A structure punch 4″ is fastened in the undepicted embossing device by means of fastening elements 3″. The fastening elements 3″ are coupled with undepicted moving and measuring devices, so that the local expansion of the structure punch 4″ from the effect of an embossing roller 6″ can be held constant, and the ellipsis error of the embodiment on FIG. 2a can be corrected. The embossing roller 6″ prestresses the structure punch 4″ under a constant expansion with a regulated stress, so that the structure punch 4″ can emboss the undepicted substrate coated with embossing material. The substrate is fastened to a substrate holder 5″ that is feedable, in particular feedable in a regulated manner. In other embodiments, the feed motion to the fixed substrate holder is performed as a relative motion.

FIG. 3 shows a schematic structural sketch of an embossing roller unit 7 according to the invention and parts of an undepicted device according to the invention. In a moving, adjusting, and guiding unit 10, an embossing roller 6″′ and a support roller 8 are installed in a regulated manner by the undepicted regulator. The embossing roller unit 7 further has a radiation source 9 preferably positioned between the embossing roller 6′″ and the support roller 8 for curing the embossing material. In particular in the gap between the embossing roller 6′″ and the support roller 8, the radiation of the radiation source 9 reaches the undepicted, structured embossing material through the structure punch 4′″ that is adjustably prestressed, in particular under a constant expansion. The undepicted substrate is fastened to a substrate holder 5′″, wherein the substrate holder 5′″ can be designed so that it can be fed in a regulated manner.

In another embodiment of the embossing roller unit 7, the prestress of the structure punch 4′″ can be adjusted via an in particular regulated change in the distance between the embossing roller 6′″ and the support roller 8. In other words, the embossing roller 6′″ and the support roller 8 clamp the structure punch 4′″ on a variable surface in at least approximately a flat manner. As a result, the ellipsis error of the devices according to the invention on FIG. 1, 2a, 2b can additionally be corrected, and the dimensional stability can be improved.

FIG. 4a shows a schematic structural sketch of a structure punch 4iv with integrated fastening elements 3iv, wherein a molding area A as well as a holding area H are denoted with corresponding functionalities. The structure punch 4iv has an edge area in the holding area H that is designed according to the lock-and-key principle to positively fasten the structure punch 4iv. In particular, the undepicted device can clamp the fastening elements 3iv without constraint, so that the structure punch 4iv is loaded with a constant prestress in all procedural steps.

FIG. 4b shows a schematic structural sketch of a structure punch 4v with integrated fastening elements 3v in an undepicted device, wherein the structure punch 4v remains under a constant expansion, in particular in a regulated manner. An undepicted substrate is fastened to the feedable substrate holder 5v. The relative motion of the structure punch 4v with the molding area A and the substrate holder 5v establishes the contact between the structure punch 4v and the embossing material, so that the structure punch 4 is molded into the embossing material. The integrated fastening elements 3v can fasten the structure punch 4v in the device, in particular free of parasitic forces, preferably without constraint, and especially preferably according to the lock-and-key principle. In other embodiments, the substrate holder 5v can be fixed, and the device with the structure punch carries out the other required motions.

FIG. 5 shows a schematic structural sketch of another embodiment of a structure punch 4vi with integrated fastening elements 3vi. In order to avoid any sudden transition of material stress in the structure punch 4vi as much as possible, an edge area with at least a half wedge-shaped, preferably (not depicted) wedge-shaped, design is generated in the holding area of the structure punch 4vi. This advantageously yields an embodiment free of notch stress.

An advantageous embodiment can be achieved with a double asymmetrical configuration of the structure punch 4vi. An asymmetry of the structure punch 4vi is preferably used to be able to distinguish in particular between an upper and lower installation position based on structural features, and to avoid an erroneous, inverted installation in the device.

Another asymmetry of the structure punch 4vi can denote a further, in particular flat coordinate direction, “right-left”, in such a way as to block an inverted installation position of the structure punch.

This embodiment of the double asymmetrical construction of the structure punch 4vi can be used in all structure punches according to the invention. An asymmetrical construction or a double asymmetrical construction of all structure punches according to the invention makes it possible to realize an application of the lock-and-key principle.

FIG. 6 shows a schematic structural sketch of a third embodiment of a structure punch 4vii. The embodiment is similar to the embodiments depicted on FIG. 4a and FIG. 5. The structure punch 4vii preferably has materially integrated solid hinges F. As a consequence, the structure punch 4vii can have varying strengths, while still having a flat molding area, in particular for rollerless embossing processes.

FIG. 7 shows a schematic structural sketch of a third embodiment of a structure punch according to FIG. 6 as part of an undepicted device according to the invention. By means of fastening elements 3viii that can be positioned and moved in a regulated manner, the undepicted device can mold the structure punch 4viii under a constant expansion, in particular with a variably regulated prestress, in an undepicted embossing material of a substrate. A substrate holder 5viii can fasten the substrate and move it in a regulated manner.

In other embodiments, a fixed substrate holder 5viii is used, and the relative motion between the substrate punch 4viii and the substrate is performed by the substrate punch.

The structure punch 4viii can form a largely flat molding area through varying strengths and solid hinges, wherein the embossing process can be introduced preferably without an embossing roller by bending the solid hinges F of the structure punch (see FIG. 6).

### REFERENCE LIST

1 Embossing device
2 Separating device
3, 3′, 3″, 3″′, 3iv, 3v, 3vi, 3viii Fastening element for the structure punch
4, 4′, 4″, 4″′, 4iv, 4v, 4vi, 4vii, 4viii Structure punch
5, 5′, 5″, 5″′, 5v, 5viii Substrate holder
6, 6′, 6″, 6′″ Embossing roller
7 Embossing roller unit
8 Support roller
9 Radiation source
10 Moving, adjusting, and guiding unit
S Starting position
E Ending position
H Holding area
A Molding area
F Solid hinge

1. A device for embossing structures in an embossing material, comprising:
a structure punch containing the structures, the structure punch being configured to emboss the structures into the embossing material, the structure punch being kept under a constant local expansion during the embossing of the structures and a separating of the structure punch from the embossing material after the embossing of the structures; and
an embossing roller for pressing the structures of the structure punch into the embossing material, the embossing roller having tappets for lifting the structure punch during the separating of the structure punch from the embossing material after the embossing of the structures.

2. The device according to claim 1, wherein, after the embossing of the structures, the embossing roller is moved from one end position on a separating path back to a starting point for renewed embossing.

3. A method for embossing structures into an embossing material, comprising:
embossing the structures into the embossing material using a structure punch containing the structures thereon, the structure punch being kept under a constant local expansion during the embossing of the structures and a separating of the structure punch from the embossing material after the embossing of the structures; and
pressing the structures of the structure punch into the embossing material with an embossing roller, the embossing roller having tappets for lifting the structure punch during the separating of the structure punch from the embossing material after the embossing of the structures.
